(19) United States
(12) Patent Application Publication
(10) Pub. No.: US 2025/0293009 A1
(43) Pub. Date: Sep. 18, 2025

(54) ADVANCED THERMAL MANAGEMENT SYSTEM (ATM) FOR PEDESTAL TEMPERATURE CONTROL IN HIGH POWER PECVD CHAMBER

(71) Applicant: Applied Materials, Inc., Santa Clara, CA (US)

(72) Inventors: Yuxing ZHANG, Santa Clara, CA (US); Abhijit KANGUDE, Fremont, CA (US); Suhas Babu PRASHAM, Bangalore (IN); Dan ZHU, Santa Clara, CA (US); Daemian Raj BENJAMIN RAJ, Fremont, CA (US); Juan C. ROCHA, San Carlos, CA (US)

(21) Appl. No.: 18/603,646

(22) Filed: Mar. 13, 2024

(51) Int. Cl. H01J 37/32; H01L 21/683

(52) U.S. Cl. CPC H01J 37/32724; H01J 37/32449; H01L 21/6833; H01J 2237/002; H01J 2237/3321

(57) ABSTRACT

Embodiments of the disclosure provided herein includes systems and methods for high power semiconductor manufacturing. The system includes a processing chamber, a substrate support assembly disposed within the processing chamber, and an advanced thermal management system coupled to the substrate support assembly. The advanced thermal management system includes one or more heating elements embedded within a body of the substrate support assembly and a cooling plate assembly embedded within the body disposed adjacent to the one or more heating elements. The cooling plate assembly includes a first cooling plate with a first cooling gas channel, a second cooling plate with a second cooling gas channel fluidly coupled to the first cooling plate by a connecting line, a supply line coupled to the first cooling gas channel, and a return line coupled to the second cooling gas channel.

### BACKGROUND

### Field

Embodiments of the present disclosure generally relate to semiconductor manufacturing and, more particularly, to a substrate support assembly suitable for high power semiconductor manufacturing.

### Description of the Related Art

PECVD, or Plasma-Enhanced Chemical Vapor Deposition, is a crucial process in semiconductor manufacturing. It involves depositing thin films onto wafers in a vacuum chamber using a plasma. The plasma is generated by applying radio frequency (RF) power to a gas mixture, which breaks down the gas molecules into reactive ions and electrons. These ions and electrons then react with the substrate surface, depositing a thin film of the desired material.

In the context of efficient plasma generation, the necessary energy to excite electrons in precursor gas molecules and ionize them, thus creating plasma, is provided by high RF power. This plasma plays a crucial role in the PECVD process by containing reactive species that engage in the deposition of the desired film. The increase in RF power results in higher electron density and energy within the plasma, leading to a more efficient dissociation of precursor gas molecules and an enhanced deposition rate. The film properties, including composition, morphology, density, and stress, are significantly influenced by high RF power. The use of high RF power in PECVD offers advantages such as faster deposition rates, improved film quality, and greater control over film properties.

Film deposition in PECVD involves the critical role of low-temperature heaters in maintaining the desired substrate temperature. Unlike traditional Chemical Vapor Deposition (CVD) processes that use high-temperature furnaces, these heaters operate at lower temperatures ranging from room temperature to 300° C. The low-temperature heaters employ various heating mechanisms, such as resistive heating, induction heating, and radiant heating, each contributing to the transfer of heat to the substrate. Precise temperature control is achieved through mechanisms like proportional-integral-derivative (PID) controllers and cooling systems. Low-temperature PECVD offers advantages, including reduced thermal stress, compatibility with sensitive materials, and reduced energy consumption. However, it is important to note that high RF power in PECVD may pose challenges, such as increased substrate heating, especially during long depositions, leading to a potential loss of temperature regulation by the heater. The temperature set points for low-temperature heaters can vary based on factors such as process requirements and the need for deposition on delicate substrates. The low-temperature range typically lies between room temperature and 300° C., while the high-temperature range is limited to 450° C. to prevent excessive thermal stress.

Accordingly, there is a need for improved systems and methods of temperature management for substrate processing.

### SUMMARY

Embodiments described herein generally relate to systems and methods used for semiconductor manufacturing. More particularly, embodiments herein provide for processes and methods having a substrate support assembly suitable for high power semiconductor manufacturing.

In an embodiment, a processing system is provided. The processing system includes a processing chamber, a substrate support assembly disposed within the processing chamber, and an advanced thermal management system coupled to the substrate support assembly, including one or more heating elements embedded within a body of the substrate support assembly, and a cooling plate assembly embedded within the body disposed adjacent to the one or more heating elements.

In another embodiment, a substrate support assembly is provided. The substrate support assembly includes an electrostatic chuck assembly disposed on a hollow support shaft, one or more heating elements embedded within a body of the substrate support assembly below the electrostatic chuck assembly, and a cooling plate assembly embedded within the body disposed adjacent to the one or more heating elements and configured to be coupled to a cooling gas source.

In yet another embodiment, a cooling plate assembly is provided. The cooling plate assembly includes a first cooling plate including a first cooling gas channel, a second cooling plate including a second cooling gas channel fluidly coupled to the first cooling plate by a connecting line, a supply line coupled to the first cooling gas channel, and a return line coupled to the second cooling gas channel.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the present disclosure and are therefore not to be considered limiting of its scope, and the present disclosure may admit to other equally effective embodiments.

FIG. 1 illustrates a schematic cross-sectional view of a processing chamber containing a substrate support assembly, according to certain embodiments.

FIG. 2 illustrates a schematic view of an advanced thermal management system, according to certain embodiments.

FIG. 3A illustrates a schematic, top view of a substrate support assembly, according to certain embodiments.

FIG. 3B illustrates a schematic, cross-sectional view of the substrate support assembly of FIG. 3A, according to certain embodiments

FIG. 3C illustrates a close-up, cross-sectional view of a portion of the substrate support assembly of FIG. 3B, according to certain embodiments

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to systems and methods for semiconductor manufacturing, and, more specifically, systems and methods having a substrate support assembly suitable for high power semiconductor manufacturing.

In plasma enhanced chemical vapor deposition (PECVD) processes, use of high radio frequency (RF) power impacts various properties of the deposited film. This includes film composition, with influences on the relative abundance of different gas species in the plasma, resulting in changes in film composition and stoichiometry. Film morphology is affected as high RF power promotes surface reactions and etching processes, impacting the film's surface roughness and texture. Additionally, film density and stress are increased, and film electrical properties such as conductivity and doping efficiency are influenced. Using high RF power in PECVD provides advantages, such as faster deposition rates, improved film quality, and greater control over film properties.

However, some potential drawbacks accompany the use of high RF power, including increased substrate heating, which can be detrimental to certain materials. In PECVD, low-temperature heaters play a critical role in maintaining the desired substrate temperature during film deposition. These heaters operate at significantly lower temperatures, typically ranging from room temperature to 300° C., unlike high-temperature furnaces used in traditional chemical vapor deposition (CVD) processes.

Low-temperature heaters in PECVD employ different heating mechanisms, such as resistive heating using a resistive element like nichrome wire, induction heating inducing eddy currents in the substrate, and radiant heating emitting infrared radiation. Precise temperature control is achieved through mechanisms like proportional-integral-derivative (PID) controllers and cooling systems, ensuring optimal film properties. The advantages of low-temperature PECVD include reduced thermal stress, compatibility with sensitive materials, and reduced energy consumption.

The set points for low-temperature heaters in PECVD can vary depending on several factors. Generally, the low-temperature range for PECVD heaters lies between room temperature and 300° C., with some processes requiring lower temperatures down to −100° C. or even cryogenic temperatures. The high-temperature range is limited to 450° C. to prevent excessive thermal stress on the substrate. However, high RF power causes the heater to lose control of temperature regulation, particularly during long depositions, leading to an upward drift in temperature. This is particularly an issue when the desired set points are in the low-temperature range, e.g., around 400° C., and the RF power exceeds 3,000 W of high-frequency RF power or 1,700 W of low-frequency RF power.

To address this temperature control issue associated with high RF power, the current state-of-the-art has two major solutions. The first solution involves flowing a dynamic liquid coolant through cooling channels within the pedestal. However, this method can lead to the liquid coolant leaking, causing system malfunction that is difficult to recover. The second solution is to completely redesign the pedestal heater to have cooling agent embedded within the heater. As the heater has to be modified, this method may significantly change the desired film properties deposited on a substrate disposed on the pedestal.

The present disclosure provides systems, apparatus, and methods for addressing the above described temperature control issue. An advanced thermal management system is provided that flows a cooling gas through channels in a cooling plate at a high flow rate to cool down the heater to maintain heater at process set points when high RF power is used in the chamber to reduce backside substrate damage and improve etch selectivity. The advanced thermal management system further provides for a mass flow controller (MFC) to control the flow rate of the cooling gas so the heater can run both a high temperature and a low temperature set point.

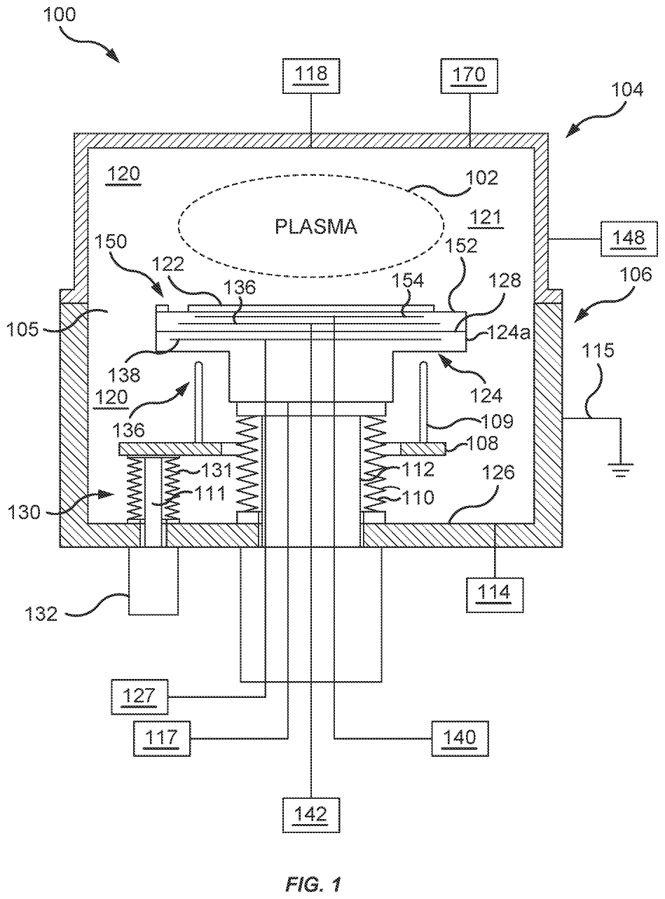

FIG. 1 depicts a schematic side view of a processing chamber 100 having a substrate support assembly 124 in accordance with at least some examples of the present disclosure. In some examples, the processing chamber 100 is an etching processing chamber. However, other types of processing chambers configured for different processes can also use or be modified for use with examples of the substrate support assembly 124 described herein.

The processing chamber 100 is a vacuum chamber that is suitably adapted to maintain sub-atmospheric pressures within a chamber interior volume 120 during substrate processing. The processing chamber 100 includes a chamber body 106 covered by a lid 104 which encloses a processing volume 121 located in the upper portion of the chamber interior volume 120 and generally above the substrate support assembly 124. The processing chamber 100 may also include one or more liners (not shown) circumscribing various chamber components to prevent unwanted reaction between such components and the gases of the processing environment within the processing chamber 100. The chamber body 106 and lid 104 may be made of metal, such as aluminum. The chamber body 106 may be grounded via a coupling, such as a ground strap, to ground 115.

The substrate support assembly 124 is disposed within the chamber interior volume 120 to support and retain a substrate 122 thereon, such as a semiconductor wafer. The substrate support assembly 124 may generally comprise an electrostatic chuck assembly 150 disposed on a hollow support shaft 112 for supporting the electrostatic chuck assembly 150. The electrostatic chuck assembly 150 comprises an electrostatic chuck 152 having one or more chucking electrodes 154 disposed therein. The electrostatic chuck 152 electrostatically chucks the substrate 122 to the substrate support assembly 124.

The hollow support shaft 112 provides a conduit to provide, for example, backside gases through backside gas lines, process gases through process gas lines, fluids through fluid lines, coolant gases through coolant lines, power cabling, or the like, to the substrate support assembly 124. In some examples, the hollow support shaft 112 is attached to a bottom surface of the chamber body 106 and the substrate support assembly 124 is fixed in the processing chamber 100. In other examples, the hollow support shaft 112 is coupled to a lift mechanism, such as an actuator or motor, which provides vertical movement of the electrostatic chuck assembly 150 between an upper, processing position (as shown in FIG. 1) and a lower, transfer position (not shown). A bellows assembly 110 is disposed about the hollow support shaft 112 and is coupled between the electrostatic chuck assembly 150 and a bottom surface 126 of processing chamber 100 to provide a flexible seal that allows vertical motion of the electrostatic chuck assembly 150 while preventing loss of vacuum from within the processing chamber 100.

The hollow support shaft 112 provides a conduit for coupling wiring or other electrical conductors between a negative pulsed DC power source 140, a bias power supply 117 to the electrostatic chuck assembly 150. In some examples, the bias power supply 117 includes one or more RF bias power sources. In some examples, the substrate support assembly 124 may alternatively include AC, DC, or RF bias power.

The substrate support assembly 124 may, or may not, include a substrate lift assembly 130. The substrate lift assembly 130 may include lift pins 109 mounted on a platform 108 connected to a shaft 111 which is coupled to a second lift mechanism 132 for raising and lowering the platform 108 and pins 109 so that the substrate 122 may be placed on or removed from the electrostatic chuck assembly 150. The electrostatic chuck assembly 150 includes through holes to receive the lift pins 109. A bellows assembly 131 is coupled between the substrate lift assembly 130 and the bottom surface 126 to provide a flexible seal that maintains the chamber vacuum during vertical motion of the substrate lift assembly 130. Alternately, the substrate lift assembly 130 may be included entirely inside the processing chamber 100, for example within the substrate support assembly 124.

The processing chamber 100 is coupled to and in fluid communication with a pumping system 114 that includes a throttle valve (not shown) and vacuum pump (not shown) which are used to exhaust the processing chamber 100. The pressure inside the processing chamber 100 may be regulated by adjusting the throttle valve and/or vacuum pump. The processing chamber 100 is also coupled to and in fluid communication with a process gas supply 118 that may supply one or more process gases to the processing chamber 100 for processing the substrate 122 disposed therein.

In operation, a plasma 102 is created in the chamber interior volume 120 to perform one or more processes. The plasma 102 may be created by coupling power from a plasma power source, e.g., RF plasma power supply 170, to a process gas via one or more electrodes (for example a coil not shown) near and exterior to the lid 104, or within the chamber interior volume 120, to ignite the process or other gas therein into a plasma 102. A bias power may also be provided from the bias power supply 117 to the one or more chucking electrodes 154 within the electrostatic chuck assembly 150 in addition to the chucking power to attract ions from the plasma 102 towards the substrate 122 to etch the exposed upper surface of the substrate 122. Alternatively, a separate substrate/body biasing electrode may be buried within the ceramic body and connected to a separate or common power supply. The RF plasma power supply 170 may provide RF energy at a frequency of about 40 MHz or greater at a desired power level to the processing chamber 100 for maintaining the plasma 102 therein. For example, the power source 142 may deliver 3,000 Watts (W) or more of high-frequency RF power, 1,000 W or more of low-frequency RF power, or both.

The substrate support assembly 124 is disposed on the hollow support shaft 112. The substrate support assembly 124 includes one or more heating elements 136 are embedded in the substrate support assembly 124. The one or more heating elements 136 may be a plate, a perforated plate, a mesh, a wire screen, or any other distributed arrangement. The one or more heating elements 136 is coupled to a power source 142. The one or more heating elements 136 can heat the substrate support to a desired temperature, such as 400° C.

The substrate support assembly 124 includes a cooling plate assembly 128. The cooling plate assembly 128 may be formed from a metal material or other suitable material. For example, the cooling plate assembly 128 may be formed from aluminum (Al). The cooling plate assembly 128 may include cooling gas channels 138 formed therein. The cooling plate assembly 128 is configured to be coupled to a cooling gas source 127, e.g., the cooling gas channels 138 may be connected to the cooling gas source 127. The cooling gas source 127 provides a cooling gas that is circulated through one or more cooling gas channels 138.

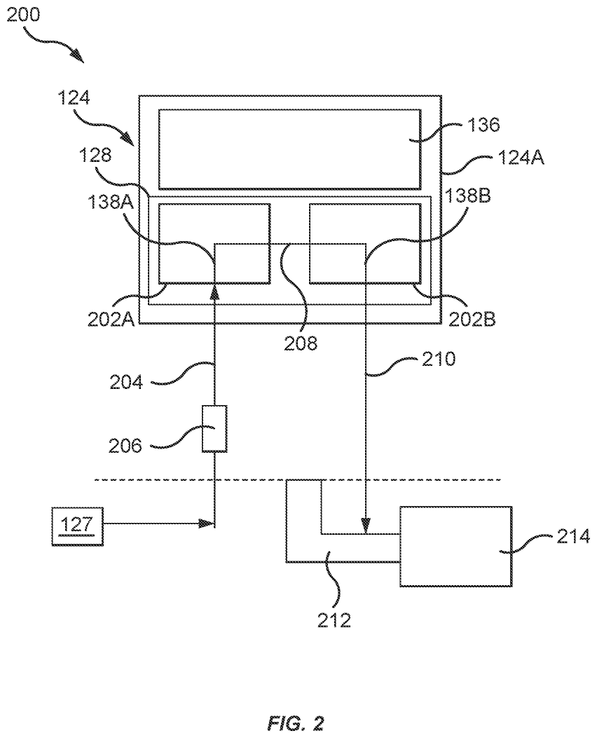

FIG. 2 illustrates a schematic view of the advanced thermal management system 200 for use with a processing system including the processing chamber 100 of FIG. 1, according to certain embodiments. The advanced thermal management system 200 includes the cooling plate assembly 128, which includes a first cooling plate 202A and a second cooling plate 202B embedded within the body 124a of the substrate support assembly 124 disposed adjacent to the one or more heating elements 136. The first cooling plate 202A is coupled to the cooling gas supply 127 through a supply line 204 configured to supply a cooling gas to the advanced thermal management system 200. A mass flow controller (MFC) 206 is disposed along the supply line 204 to control the flow rate of the cooling gas into the first cooling plate 202A. The first cooling plate 202A and the second cooling plate 202B are fluidly coupled by a connecting line 208 that connects the cooling channels of the first cooling plate 202A, e.g., a first cooling gas channel 138a, to the cooling channels of the second cooling plate 202B, e.g., a second cooling gas channel 138b, such that the cooling gas may flow from the first cooling plate 202A to the second cooling plate 202B. The second cooling plate 202B is also fluidly coupled to a return line 210. The return line 210 may be coupled to a vacuum pumping system, e.g., pumping system 114, an exhaust 212, a scrubber 214, or a combination thereof.

The MFC 206 is configured to flow a cooling gas through the supply line 204 at a high flow rate, such as 5 gallons per minute (GPM) or more, such as 10 GPM or more, such as 20 GPM or more, such as 30 GPM or more. The flow rate of the cooling gas is dependent on the gas chosen to flow and a desired heat transfer coefficient for the overall system.

The heat transfer coefficient, which signifies the transfer of heat between a solid surface and a moving fluid, directly impacts the convective heat transfer that occurs between the cooling gas channels, e.g., the first cooling gas channel 138a and the second cooling gas channel 138b, and the body 124a of the substrate support 124. The better the heat transfer coefficient of the fluid flowing in the cooling gas channels, the better performance exhibited by the cooling plate assembly 128. The rate of heat transfer is directly impacted by heat transfer coefficient and is typically described by the following equation:

Q=hAΔT,

where Q is the rate of heat transfer (W), h is the heat transfer coefficient (W/m²K), A is the area of the surface (m²), and ΔT is the temperature difference between the surface and the fluid (K).

A higher heat transfer coefficient signifies a more efficient transfer of heat between the body 124a of the 124 and the cooling gas flowed in the cooling gas channel 138. As the value of the heat transfer coefficient increases, the rate of heat transfer also increases for a given surface area and temperature difference. This allows for faster cooling of the surface. A higher heat transfer coefficient also produces a more efficient heat transfer process as indicated by a higher value of h, resulting in less energy wasted and a more effective cooling system. The heat transfer coefficient may be impacted by various fluid properties, including viscosity, density, thermal conductivity, and flow velocity. Higher viscosity and density, as well as increased thermal conductivity and flow velocity, generally lead to a higher heat transfer coefficient.

The heat transfer coefficient increases with an increasing gas flow rate due to a higher Reynolds number, resulting in a higher Nusselt number and ultimately a higher heat transfer coefficient. The Reynolds number characterizes the flow regime of a fluid, representing the ratio of inertial forces to viscous forces. The Nusselt number characterizes the heat transfer between a fluid and a solid surface, representing the ratio of convective heat transfer to conductive heat transfer. The heat transfer coefficient, measured in units of W/m² K, indicates how easily heat can be transferred between a fluid and a solid surface.

Further, it is generally easier to flow gases at higher rates than liquids in a channel. Gases, with significantly lower viscosity than liquids, exhibit less resistance to flow. Additionally, their lower density allows for easier acceleration and deceleration, facilitating control over flow rates. The compressibility of gases enables the use of pumps to increase their flow rate, a capability not easily achievable with almost incompressible liquids.

Using high flow rate cooling gas, such as N₂, to cool down the heater cooling plate will pull out heat and maintain the heater at a process set point more efficiently than a liquid coolant as the cooling gas can achieve higher flow rates and, subsequently, better heat transfer coefficients. The cooling gas is isolated from the process gases within the chamber and will only flow through the cooling channels within the cooling plate, not impacting process flow. In embodiments where the chamber includes a post pump purge, e.g., a 100 standard liter per minute (sim) post pump N₂ purge, the return line 210 may be routed to the chamber and return to the post pump location for abatement in the vacuum system. If abatement is not configured to process the high flow rate of the cooling gas, the scrubber 214 may be the return location as well.

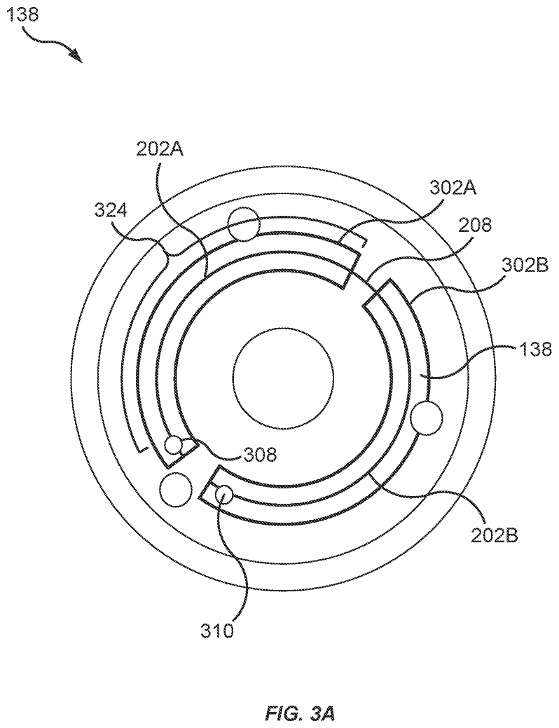

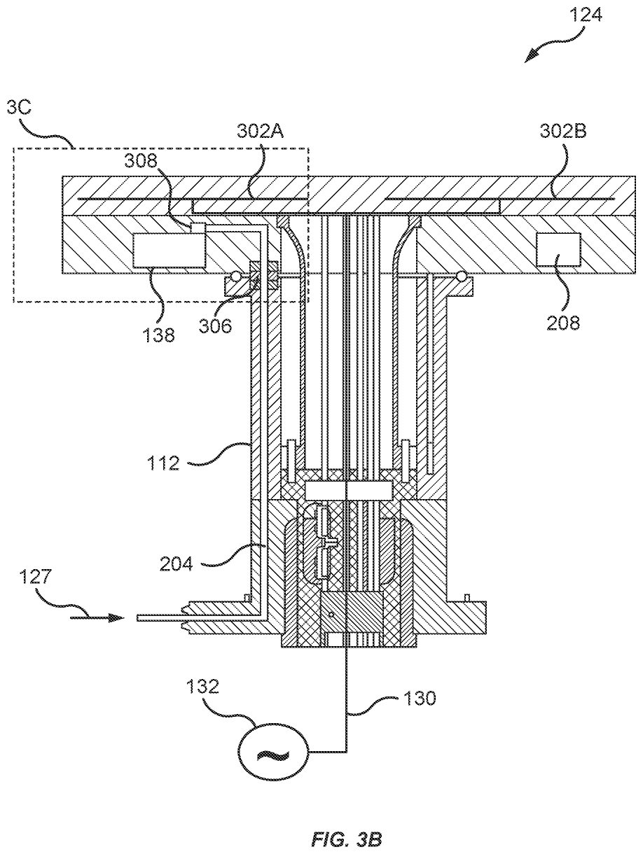

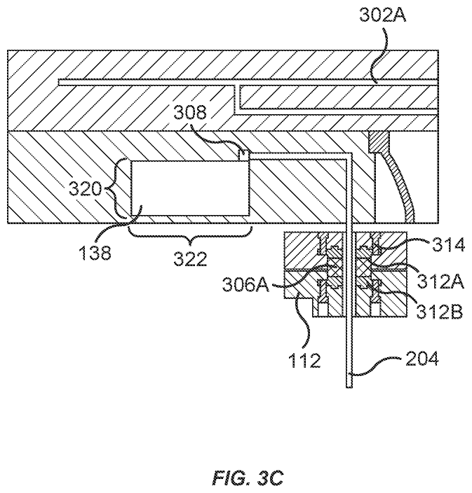

FIG. 3A illustrates a schematic, top view of the substrate support assembly 124, according to certain embodiments. FIG. 3B illustrates a schematic, cross-sectional view of the substrate support assembly 124 taken along line 3B-3B, according to certain embodiments. FIG. 3C illustrates a close-up, cross-sectional view of a portion of the substrate support assembly 124, according to certain embodiments.

As shown in FIG. 3A, the substrate support assembly 124 includes a first heating element 302A on one side of the substrate support assembly 124 and a second heating element 302B on another side of the substrate support assembly 124, opposing the first heating element 302A. The first heating element 302A and the second heating element 302B may be connected to a power source, such as power source 142 (FIG. 1). The first heating element 302A may be connected to the same power source as the second heating element 302B. Alternatively, each of the first heating element 302A and the second heating element 302B may be connected to different power sources (not shown) for independent or zone heating. The first heating element 302A and the second heating element 302B are embedded in the body 124a. The first heating element 302A and the second heating element 302B extend horizontally within the body 124a to a distance from an outer diameter of the body 124a. In one example, the distance the first heating element 302A and the second heating element 302B extend horizontally within the body 124a is between about 5 mm and about 15 mm, such as about 10 mm from the outer diameter of the body 124a.

The first heating element 302A and the second heating element 302B may be arranged in one or more zones to control a temperature of the substrate support assembly 124. For example, the first heating element 302A and the second heating element 302B may be arranged in one, two, or four zones for supplying a temperature to the substrate support assembly 124. The first heating element 302A and the second heating element 302B may have a hollow region in the center of the diameter of the body 124a through which power supply wires may pass. The first heating element 302A and the second heating element 302B are coupled to a power source 142 (FIG. 1), e.g., an AC power source, to power the first heating element 302A and the second heating element 302B. The first heating element 302A and the second heating element 302B are configured to supply a temperature to the substrate of about 100° C. to about 600° C. For example, the electrostatic chuck 152 is configured to operate at temperatures exceeding 300° C., such as about 400° C.

The substrate support assembly 124 includes the cooling plate assembly 128 (FIGS. 1 and 2) beneath the first heating element 302A and the second heating element 302B. The cooling plate assembly 128 includes the cooling gas channel 138 (FIG. 1). The cooling gas channel 138 is coupled to the advanced thermal management system 200 through the supply line 204 (FIG. 3B) at a supply port 308. The cooling gas channel 138 is configured to allow a high flow rate of a cooling gas to pass through the cooling gas channel 138 from the supply port 308 to a return port 310 at the end of the cooling gas channel 138. The cooling gas may include, but is not limited to, helium (He), nitrogen (N₂), argon (Ar), and air. The cooling gas may be flowed at a rate to improve the overall heat transfer coefficient.

The cooling gas channel 138 includes a height 320 (FIG. 3C), a width 322 (FIG. 3C), and a length 324. Preferably, the height 320 would be low and the length 324 would be large to increase contact area of the cooling gas channel 138 along a plane parallel to the surface of the substrate support, e.g., to increase the cooling channel surface area in reference to a substrate placed on the substrate support. Further, a lower height 320 increases the overall heat transfer coefficient and leads to improved effective thermal conductivity of the cooling plate assembly 128. As such, the cooling gas channel would include a width-to-height ratio of greater than 1:1. Further, the first cooling plate 202A includes a first width-to-height ratio and the second cooling plate 202B includes a second width-to-height ratio. The first width-to-height ratio and the second width-to-height ratio may be the same to provide uniform cooling across both the first cooling plate 202A and the second cooling plate 202B. Alternatively, the first width-to-height ratio and the second width-to-height ratio may be different to provide more tuned cooling of the first cooling plate 202A and the second cooling plate 202B.

As shown in FIG. 3B, the supply line 204 flows from a base of the hollow support shaft 112 of the substrate support assembly 124 through the hollow support shaft 112 and connects to the supply port 308 such that the supply line 204 is fluidly coupled to the cooling gas channel 138. In certain embodiments where the substrate support assembly 124 is configured to vertically displace, the cooling plate assembly 128 includes a channel bellows assembly 306 at the junction of the hollow support shaft 112 and the body 124a. The cooling gas may be flowed at high flow rates, such as 5 gallons per minute (GPM) or more, such as 10 GPM or more, such as 20 GPM or more, such as 30 GPM or more.

As shown in FIG. 3C, the channel bellows assembly 306 includes a channel bellows body 306A coupled to a top gasket 312A, coupled to the body 124a by fasteners 314, and a bottom gasket 312B, coupled to the hollow support shaft 112 by fasteners 314. The channel bellows assembly 306 is concentrically aligned with the supply line 204 such that the supply line 204, the channel bellows assembly 306, and the cooling gas channel 138 are in fluid communication. As the substrate support assembly 124 travels upward, the channel bellows assembly 306 expands with the body 124a to maintain fluid communication between the cooling gas source 127 and the cooling gas channel 138 through the supply line 204. The channel bellows assembly 306 is used to serve the compliance design where the cooling plate assembly 128 is pushed up by spring rods. This allows the cooling plate assembly 128 to maintain contact with the first heating element 302A and the second heating element 302B (FIG. 3A) to effectively drain heat from each.

The present disclosure provides an advanced thermal management system that flows a cooling gas through channels in a cooling plate, within a substrate support, at a high flow rate to cool down the heater and maintain the heater at process set points when high RF power is used in the chamber, thus, reducing backside substrate damage and improving etch selectivity.

When introducing elements of the present disclosure or exemplary aspects or embodiments thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another—even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A processing system, comprising:
a processing chamber;
a substrate support assembly disposed within the processing chamber; and
an advanced thermal management system coupled to the substrate support assembly, comprising:
one or more heating elements embedded within a body of the substrate support assembly; and
a cooling plate assembly embedded within the body disposed adjacent to the one or more heating elements.

2. The processing system of claim 1, wherein the cooling plate assembly is coupled to a mass flow controller configured to flow a cooling gas through the cooling plate assembly at about 20 gallons per minute or more.

3. The processing system of claim 1, wherein the cooling plate assembly is configured to be coupled to a cooling gas source and wherein the cooling gas is He, N₂, Ar, air, or a combination thereof.

4. The processing system of claim 1, wherein the cooling plate assembly includes a cooling gas channel configured to flow a cooling gas.

5. The processing system of claim 1, wherein the cooling plate assembly comprises a first cooling plate and a second cooling plate, the first cooling plate and the second cooling plate fluidly coupled by a connecting line.

6. The processing system of claim 5, wherein the first cooling plate is coupled to a supply line at a supply port within the body and the second cooling plate coupled to a return line at a return port within the body.

7. The processing system of claim 6, wherein the return line is fluidly coupled to a vacuum pump of the processing system.

8. A substrate support assembly, comprising:
an electrostatic chuck assembly disposed on a hollow support shaft;
one or more heating elements embedded within a body of the substrate support assembly below the electrostatic chuck assembly; and
a cooling plate assembly embedded within the body disposed adjacent to the one or more heating elements and configured to be coupled to a cooling gas source.

9. The substrate support assembly of claim 8, wherein the cooling plate assembly further comprises a first cooling plate including a cooling gas channel configured to be coupled to the cooling gas source by a supply line disposed within the hollow support shaft.

10. The substrate support assembly of claim 9, wherein the cooling plate assembly includes a channel bellows assembly disposed between the hollow support shaft and the body of the substrate support assembly.

11. The substrate support assembly of claim 10, wherein the channel bellows assembly includes a channel bellows body concentrically aligned with the supply line such that the supply line, the channel bellows assembly, and the cooling gas channel are in fluid communication.

12. The substrate support assembly of claim 8, wherein the cooling plate assembly is coupled to a mass flow controller configured to flow a cooling gas through the cooling plate assembly at about 20 gallons per minute or more.

13. The substrate support assembly of claim 8, wherein the cooling gas channel includes a length, a height, and a width-to-height ratio of greater than 1:1.

14. The substrate support assembly of claim 8, wherein the cooling gas is He, N₂, Ar, air, or a combination thereof.

15. A cooling plate assembly, comprising:
a first cooling plate including a first cooling gas channel;
a second cooling plate including a second cooling gas channel fluidly coupled to the first cooling plate by a connecting line;
a supply line coupled to the first cooling gas channel; and
a return line coupled to the second cooling gas channel.

16. The cooling plate of claim 15, wherein the supply line is configured to supply a cooling gas to the first cooling gas channel and the second cooling gas channel.

17. The cooling plate of claim 16, wherein the supply line is further coupled to a mass flow controller configured to flow the cooling gas at 20 gallons per minute or more.

18. The cooling plate of claim 15, wherein the first cooling gas channel includes a length, a height, and a width-to-height ratio of greater than 1:1.

19. The cooling plate of claim 18, wherein the second cooling gas channel includes a length, a height, and a width-to-height ratio, wherein the width-to-height ratio of the first cooling gas channel and the width-to-height ratio of the second cooling gas channel are different.

20. The cooling plate of claim 16, wherein the cooling gas is He, N₂, Ar, air, or a combination thereof.
